(19) United States
(12) Patent Application Publication
(10) Pub. No.: US 2025/0323622 A1
(43) Pub. Date: Oct. 16, 2025

(54) ISOLATION USING MICRO/NANOSCALE PIEZOELECTRIC ACOUSTIC RESONATOR STRUCTURES

(71) Applicant: Analog Devices, Inc., Wilmington, MA (US)

(72) Inventors: Adarsh Ravi, Woburn, MA (US); Baoxing Chen, Westford, MA (US); Jinglin Xu, Reading, MA (US)

(73) Assignee: Analog Devices, Inc., Wilmington, MA (US)

(21) Appl. No.: 18/635,382

(22) Filed: Apr. 15, 2024

(51) Int. Cl. H03H 9/25; H03H 9/02; H03H 9/145

(52) U.S. Cl. CPC H03H 9/25; H03H 9/02724; H03H 9/14561

(57) ABSTRACT

Described herein are techniques for enhancing isolation in on-chip piezoelectric-based isolators. Several techniques are described that improve isolation in piezoelectric isolators. According to an aspect of the present disclosure, a piezoelectric isolator may include structures arranged to decrease the occurrence of pockets of high electric field and/or to increase the breakdown electric field in the path from the transmitter to the receiver. Further aspects of the present disclosure relate to techniques for increasing the efficiency of piezoelectric isolators while also limiting the formation of spurious signals. The inventors have developed techniques for promoting propagation of surface acoustic waves toward the receiver while limiting propagation in the opposite direction.

### BACKGROUND

### Field

The present application relates to piezoelectric isolators.

### Related Art

The piezoelectric effect is a phenomenon by which certain materials generate an electric charge when mechanical stress is applied to them. Conversely, these materials also exhibit mechanical deformation in response to an applied electric field. This effect occurs due to the arrangement of atoms within the crystal lattice of these materials. When mechanical stress is applied, it causes a displacement of positive and negative charges within the lattice structure, resulting in the generation of an electric potential across the material. This effect is reversible in that when an electric field is applied, it can cause the material to deform.

Piezoelectric sensors are devices that utilize the piezoelectric effect to measure various physical quantities such as pressure, force, acceleration, and strain. These sensors are designed to convert mechanical stress or strain into an electrical signal, which can then be measured and analyzed. Piezoelectric sensors typically consist of a piezoelectric material, such as quartz, ceramics, or certain polymers, and electrodes for capturing the generated electrical charge. When mechanical stress is applied to the sensor, it causes the piezoelectric material to deform slightly, resulting in the displacement of positive and negative charges within the material's crystal lattice. This displacement generates an electric potential across the material, which is then measured by the electrodes as an electrical signal.

### BRIEF SUMMARY

Described herein are techniques for enhancing isolation in on-chip piezoelectric-based isolators. Several techniques are described that improve isolation in piezoelectric isolators. According to an aspect of the present disclosure, a piezoelectric isolator may include structures arranged to decrease the occurrence of pockets of high electric field and/or to increase the breakdown electric field in the path from the transmitter to the receiver. Further aspects of the present disclosure relate to techniques for increasing the efficiency of piezoelectric isolators while also limiting the formation of spurious signals. The inventors have developed techniques for promoting propagation of surface acoustic waves toward the receiver while limiting propagation in the opposite direction.

Some embodiments relate to a piezoelectric isolator, comprising: a substrate comprising a piezoelectric material; a piezoelectric transmitter, disposed on the substrate, having a first electrode structure; a piezoelectric receiver, disposed on the substrate, having a second electrode structure, wherein the piezoelectric transmitter is acoustically coupled to the piezoelectric receiver at least partially through the piezoelectric material; and a first dielectric material layer disposed between the first electrode structure and the piezoelectric material.

In some embodiments, the piezoelectric material has a first dielectric constant and the first dielectric material layer has a second dielectric constant less than the first dielectric constant.

In some embodiments, the piezoelectric material is made of lithium niobate or zinc oxide or gallium nitride or aluminum nitride or lithium tantalate or quartz.

In some embodiments, the first dielectric material layer is made of silicon nitride or aluminum nitride or boron nitride or aluminum oxide or silicon dioxide.

In some embodiments, the first electrode structure forms a first interdigitated transducer (IDT) and the second electrode structure forms a second IDT.

In some embodiments, the first dielectric material layer has a thickness that is between 100 nm and 300 nm.

In some embodiments, the piezoelectric isolator further comprises a second dielectric material layer covering the first electrode structure; and a third dielectric material layer disposed on the second dielectric material layer.

In some embodiments, the second dielectric material comprises silicon oxide and the third dielectric material layer comprises a polymer.

In some embodiments, the second dielectric material has a thickness less than 2 μm and the third dielectric material layer has a thickness greater than 2 μm.

In some embodiments, the piezoelectric isolator further comprises a dielectric material region disposed between the piezoelectric transmitter and the piezoelectric receiver, wherein: the piezoelectric material has a first dielectric strength, and the dielectric material region has a second dielectric strength greater than the first dielectric strength.

In some embodiments, the piezoelectric isolator further comprises an acoustic reflector, wherein the piezoelectric transmitter is disposed between the acoustic reflector and the piezoelectric receiver.

In some embodiments, the piezoelectric isolator further comprises an acoustic absorber, wherein the piezoelectric receiver is disposed between the acoustic absorber and the piezoelectric transmitter.

In some embodiments, the piezoelectric isolator further comprising electronic circuitry co-integrated with the substrate.

In some embodiments, wherein the piezoelectric transmitter comprises a plurality of electrodes and a plurality of phase shifters, coupled to the electrodes, configured to perform beamforming.

Some embodiments relate to a piezoelectric isolator, comprising a substrate comprising a piezoelectric material; a piezoelectric transmitter disposed on the substrate; a piezoelectric receiver, disposed on the substrate, acoustically coupled to the piezoelectric transmitter at least partially through the piezoelectric material; and means for reducing a local electric field in a region of the piezoelectric material near the piezoelectric transmitter.

In some embodiments, the means for reducing the local electric field comprises a first dielectric material layer disposed between the piezoelectric transmitter and the piezoelectric material.

In some embodiments, the piezoelectric material has a first dielectric constant and the first dielectric material layer has a second dielectric constant less than the first dielectric constant.

Some embodiments relate to a method for manufacturing a piezoelectric isolator, comprising obtaining a substrate comprising a piezoelectric material; forming a first dielectric material layer on the piezoelectric material; patterning the substrate to define: a piezoelectric transmitter with a first electrode structure on the substrate so that the first dielectric material layer is between the first electrode structure and the piezoelectric material; and a piezoelectric receiver with a second electrode structure on the substrate.

In some embodiments, the piezoelectric material has a first dielectric constant and the first dielectric material layer has a second dielectric constant less than the first dielectric constant.

In some embodiments, the first dielectric material layer, when formed, has a thickness that is between 100 nm and 300 nm.

Some embodiments relate to a piezoelectric isolator, comprising a substrate comprising a piezoelectric material; a piezoelectric transmitter disposed on the substrate; a piezoelectric receiver disposed on the substrate, wherein the piezoelectric transmitter is acoustically coupled to the piezoelectric receiver at least partially through the piezoelectric material; and a dielectric material region disposed between the piezoelectric transmitter and the piezoelectric receiver, wherein: the piezoelectric material has a first dielectric strength, and the dielectric material region has a second dielectric strength greater than the first dielectric strength.

In some embodiments, the dielectric material region has a thickness that is between 1 micron and 5 microns.

In some embodiments, the dielectric material region comprises silicon dioxide.

In some embodiments, the dielectric material region comprises a well formed into the piezoelectric material.

In some embodiments, the piezoelectric material is made of lithium niobate or zinc oxide or gallium nitride or aluminum nitride or lithium tantalate or quartz.

In some embodiments, the piezoelectric transmitter comprises a first interdigitated transducer (IDT) and the piezoelectric receiver comprises a second IDT.

In some embodiments, the piezoelectric isolator further comprises an acoustic reflector, wherein the piezoelectric transmitter is disposed between the acoustic reflector and the piezoelectric receiver.

In some embodiments, the piezoelectric isolator further comprises an acoustic absorber, wherein the piezoelectric receiver is disposed between the acoustic absorber and the piezoelectric transmitter.

In some embodiments, the piezoelectric transmitter is a first piezoelectric transmitter, and wherein the piezoelectric isolator further comprises a second piezoelectric transmitter.

In some embodiments, the piezoelectric receiver is disposed between the first piezoelectric transmitter and the second piezoelectric transmitter.

In some embodiments, the piezoelectric transmitter defines a primary axis of acoustic propagation that is parallel to a direction of maximum piezoelectric coupling of the substrate.

In some embodiments, the substrate defines a direction of maximum piezoelectric coupling of the substrate and the piezoelectric transmitter defines a primary axis of acoustic propagation, wherein the direction of maximum piezoelectric coupling and the primary axis of acoustic propagation are transverse relative to one another.

Some embodiments relate to a piezoelectric isolator, comprising a substrate comprising a piezoelectric material; a piezoelectric transmitter disposed on the substrate; a piezoelectric receiver, disposed on the substrate, acoustically coupled to the piezoelectric transmitter at least partially through the piezoelectric material; and means for increasing a breakdown electric field between the piezoelectric transmitter and the piezoelectric receiver.

In some embodiments, the means for increasing the breakdown electric field comprises a dielectric material region disposed between the piezoelectric transmitter and the piezoelectric receiver.

In some embodiments, the piezoelectric material has a first dielectric strength, and the dielectric material region has a second dielectric strength greater than the first dielectric strength.

In some embodiments, the piezoelectric material is made of lithium niobate and dielectric material region comprises silicon dioxide.

In some embodiments, the means for reducing the local electric field comprises silicon dioxide.

Some embodiments relate to a method for manufacturing a piezoelectric isolator, comprising obtaining a substrate comprising a piezoelectric material; forming a dielectric material region; patterning the substrate to define a piezoelectric transmitter with a first electrode structure on the substrate; and a piezoelectric receiver with a second electrode structure on the substrate so that the dielectric material region is between the first electrode structure and the second electrode structure.

In some embodiments, the piezoelectric material has a first dielectric strength, and the dielectric material region has a second dielectric strength greater than the first dielectric strength.

In some embodiments, the piezoelectric material is made of lithium niobate and dielectric material region comprises silicon dioxide.

Some embodiments relate to a piezoelectric isolator, comprising a substrate comprising a piezoelectric material; a piezoelectric transmitter, disposed on the substrate, having a first electrode structure; a piezoelectric receiver, disposed on the substrate, having a second electrode structure, wherein the piezoelectric transmitter is acoustically coupled to the piezoelectric receiver at least partially through the piezoelectric material; an acoustic reflector, wherein the piezoelectric transmitter is disposed between the acoustic reflector and the piezoelectric receiver; and an acoustic absorber, wherein the piezoelectric receiver is disposed between the acoustic absorber and the piezoelectric transmitter.

In some embodiments, the acoustic reflector comprises a periodic structure.

In some embodiments, the acoustic absorber comprises a layer of absorbing material configured to attenuate acoustic waves.

In some embodiments, the first electrode structure comprises rounded corners.

In some embodiments, the piezoelectric transmitter defines a primary axis of acoustic propagation that is parallel to a direction of maximum piezoelectric coupling of the substrate.

In some embodiments, the piezoelectric isolator further comprises first and second contacts electrically coupled to the piezoelectric transmitter, wherein the first and second contacts are separated by a distance, and wherein the distance does not support spurious waves.

In some embodiments, the distance is not a multiple of a resonant wavelength of the piezoelectric transmitter.

In some embodiments, the piezoelectric material is made of lithium niobate or zinc oxide or gallium nitride or aluminum nitride or lithium tantalate or quartz.

In some embodiments, the piezoelectric isolator further comprises a first dielectric material layer disposed between the first electrode structure and the piezoelectric material.

In some embodiments, the first electrode structure forms a first interdigitated transducer (IDT) and the second electrode structure forms a second IDT.

In some embodiments, the piezoelectric isolator further comprises a dielectric material region disposed between the piezoelectric transmitter and the piezoelectric receiver, wherein: the piezoelectric material has a first dielectric strength, and the dielectric material region has a second dielectric strength different from the first dielectric strength.

Some embodiments relate to a piezoelectric isolator, comprising a substrate comprising a piezoelectric material; a piezoelectric transmitter disposed on the substrate; a piezoelectric receiver, disposed on the substrate, acoustically coupled to the piezoelectric transmitter at least partially through the piezoelectric material; and means for promoting propagation of surface acoustic waves in a first direction on the substrate and for limiting propagation of surface acoustic waves on the substrate in second direction opposite the first direction.

In some embodiments, the means comprises an acoustic reflector and an acoustic absorber.

In some embodiments, the piezoelectric transmitter is disposed between the acoustic reflector and the piezoelectric receiver; and the piezoelectric receiver is disposed between the acoustic absorber and the piezoelectric transmitter.

In some embodiments, the acoustic reflector comprises a periodic structure.

In some embodiments, the acoustic absorber comprises a layer of absorbing material configured to attenuate acoustic waves.

Some embodiments relate to a method for manufacturing a piezoelectric isolator, comprising obtaining a substrate comprising a piezoelectric material; patterning the substrate to define a piezoelectric transmitter with a first electrode structure on the substrate, a piezoelectric receiver with a second electrode structure on the substrate, and an acoustic reflector on the substrate such that the piezoelectric transmitter is disposed between the acoustic reflector and the piezoelectric receiver; and forming an absorber layer on the substrate such that the piezoelectric receiver is disposed between the absorber layer and the piezoelectric transmitter.

In some embodiments, the acoustic reflector comprises a periodic structure.

In some embodiments, the absorber layer comprises a layer of absorbing material configured to attenuate acoustic waves.

Some embodiments relate to a piezoelectric isolator, comprising a substrate comprising a piezoelectric material; a first piezoelectric receiver, disposed on the substrate, having a first electrode structure; a piezoelectric transmitter, disposed on the substrate, having a second electrode structure; and a second piezoelectric receiver, disposed on the substrate, having a third electrode structure, wherein the piezoelectric transmitter is acoustically coupled to the first piezoelectric receiver and the second piezoelectric receiver at least partially through the piezoelectric material.

In some embodiments, the piezoelectric isolator further comprises an acoustic absorber, wherein the first piezoelectric receiver is disposed between the piezoelectric transmitter and the acoustic absorber.

In some embodiments, the acoustic absorber comprises a layer of absorbing material configured to attenuate acoustic waves.

In some embodiments, the first and the second electrode structure comprises rounded corners.

In some embodiments, the piezoelectric transmitter defines a primary axis of acoustic propagation that is parallel to a direction of maximum piezoelectric coupling of the substrate.

In some embodiments, the piezoelectric isolator further comprises first and second contacts electrically coupled to the piezoelectric transmitter that are separated by a distance, and wherein the distance does not support spurious waves generation.

In some embodiments, the distance is not a multiple of a resonant wavelength of the piezoelectric transmitter.

In some embodiments, the piezoelectric material is made of lithium niobate.

In some embodiments, the piezoelectric isolator further comprises a first dielectric material layer disposed between the second electrode structure and the piezoelectric material.

In some embodiments, the first electrode structure forms a first interdigitated transducer (IDT), the second electrode structure forms a second IDT, and the third electrode structure forms a third IDT.

In some embodiments, the piezoelectric isolator further comprises a first dielectric material region disposed between the piezoelectric transmitter and the first piezoelectric receiver and a second dielectric material region disposed between the piezoelectric transmitter and the second piezoelectric receiver.

In some embodiments, the piezoelectric material has a first dielectric strength, and the first and second dielectric material regions have a second dielectric strength greater than the first dielectric strength.

In some embodiments, the piezoelectric isolator further comprises electronic circuitry co-integrated with the substrate.

In some embodiments, the piezoelectric transmitter comprises a plurality of electrodes and a plurality of phase shifters, coupled to the electrodes, configured to perform beamforming.

Some embodiments relate to a piezoelectric isolator, comprising a substrate comprising a piezoelectric material; a first piezoelectric transmitter, disposed on the substrate, having a first electrode structure; a piezoelectric receiver, disposed on the substrate, having a second electrode structure; and a second piezoelectric transmitter, disposed on the substrate, having a third electrode structure, wherein the piezoelectric receiver is acoustically coupled to the first piezoelectric transmitter and the second piezoelectric transmitter at least partially through the piezoelectric material.

In some embodiments, the piezoelectric isolator further comprises a first acoustic reflector, wherein the first piezoelectric transmitter is disposed between the first acoustic reflector and the piezoelectric receiver; and a second acoustic reflector, wherein the second piezoelectric transmitter is disposed between the second acoustic reflector and the piezoelectric receiver.

In some embodiments, the first acoustic reflector comprises a periodic structure.

In some embodiments, the piezoelectric isolator further comprises a first dielectric material region disposed between the first piezoelectric transmitter and the piezoelectric receiver and a second dielectric material region disposed between the second piezoelectric transmitter and the piezoelectric receiver.

In some embodiments, the first piezoelectric transmitter defines a primary axis of acoustic propagation that is parallel to a direction of maximum piezoelectric coupling of the substrate.

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in all the figures in which they appear.

FIG. 1 illustrates a piezoelectric isolator, according to some embodiments.

FIG. 2 shows a sectional view of a piezoelectric isolator, according to some embodiments.

FIG. 3 shows a sectional view of a piezoelectric isolator including a dielectric material region, according to some embodiments.

FIG. 4 shows a flowchart of a method for manufacturing a piezoelectric isolator, according to some embodiments.

FIG. 5A shows a sectional view of a piezoelectric isolator including a non-planar arrangement, according to some embodiments.

FIG. 5B shows a sectional view of a piezoelectric isolator including another non-planar or stack/multi-layered arrangement, according to some embodiments.

FIGS. 6A and 6B show sectional views of a piezoelectric isolator including a region capable of providing an opening for wirebonds or chip-chip interconnect blocks, according to some embodiments.

FIG. 7 shows components of a piezoelectric isolator including an acoustic reflector and an acoustic absorber, according to some embodiments.

FIG. 8 shows a flowchart of a method for manufacturing a piezoelectric isolator, according to some embodiments.

FIG. 9 shows a sectional view of a piezoelectric isolator including an acoustic absorber, according to some embodiments.

FIG. 10 shows a top view of a piezoelectric isolator, according to some embodiments.

FIG. 11 shows a top view of a portion of an electrode structure, according to some embodiments.

FIG. 12 shows a top view of a piezoelectric isolator, according to some embodiments.

FIG. 13 shows a top view of a wafer used in manufacturing a piezoelectric isolator, according to some embodiments.

FIGS. 14A and 14B show sectional views of piezoelectric isolators including an indication of the direction of piezoelectric coupling, according to some embodiments.

FIG. 15A shows a top view of pads of a piezoelectric isolator in two different configurations, according to some embodiments.

FIG. 15B shows a sectional view of a pad of a piezoelectric isolator, according to some embodiments.

FIG. 16A shows a top view of an alternative transducer arrangement of a piezoelectric isolator, according to some embodiments.

FIG. 16B shows a sectional view of the piezoelectric isolator of FIG. 16A, according to some embodiments.

FIG. 16C shows a top view of another alternative transducer arrangement of a piezoelectric isolator, according to some embodiments.

FIG. 16D shows a sectional view of the piezoelectric isolator of FIG. 16C, according to some embodiments.

### DETAILED DESCRIPTION

Described herein are techniques for enhancing isolation in on-chip piezoelectric-based isolators. The inventors have recognized and appreciated the need to integrate piezoelectric isolators on semiconductor substrates. This enables chip designs in which multiple piezoelectric isolators are combined on the same chip and/or chip designs in which a piezoelectric isolator is combined with other electronic devices and circuits, such as drivers, amplifiers, filters, etc. The ability to integrate piezoelectric isolators with other components leads to several benefits, including reduced manufacturing costs, reduced power consumptions and increased design flexibility.

However, integrating piezoelectric isolators on-chip poses a challenge. Piezoelectric materials tend to have poor dielectric characteristics. Examples of piezoelectric materials that may be used with the isolators described herein include lithium niobate, zinc oxide, gallium nitride, zinc oxide, aluminum nitride, lithium tantalate and quartz, among other possible materials. Some of these materials (e.g., lithium niobate) are incompatible with traditional IC manufacturing process, although they can be co-fabricated with conventional semiconductor substrates using bonding. For example, a lithium niobate substrate can be bonded to a silicon substrate that includes complementary metal-oxide-semiconductor (CMOS) circuitry, thereby allowing co-integration of isolators with electronic circuitry. As another example, a piezoelectric material substrate can be bonded to a sapphire substrate or to a gallium nitride substrate. Unfortunately, piezoelectric materials tend to have a relatively high dielectric constant and a relatively low dielectric strength. The relatively high dielectric constant can result in pockets of high electric field. At the same time, the relatively low dielectric strength provides a thin margin against high electric fields before electric breakdown occurs. These two characteristics, in combination, make piezoelectric materials less-than-ideal candidate to provide galvanic isolation in that they are particularly susceptible to electric breakdown.

Described herein are several techniques to improve isolation in piezoelectric isolators. According to an aspect of the present disclosure, a piezoelectric isolator may include structures arranged to decrease the occurrence of pockets of high electric field and/or to increase the breakdown electric field in the path from the transmitter to the receiver. In some embodiments, a dielectric material layer may be disposed between the piezoelectric transmitter (and/or the receiver) and the piezoelectric material. The dielectric material layer may have a dielectric constant that is less than the dielectric constant of the piezoelectric material. As a result, the occurrence of pockets of high electric field near the electrodes is reduced (the regions near the electrodes are generally susceptible to produce high electric fields). Additionally, or alternatively, a dielectric material region may be disposed between the piezoelectric transmitter and the piezoelectric receiver. The dielectric material region may have a dielectric strength that is greater than the dielectric strength of the piezoelectric material. As a result, the breakdown electric field in the path from the transmitter to the receiver is increased.

Further aspects of the present disclosure relate to techniques for increasing the efficiency of piezoelectric isolators while also limiting the formation of spurious signals. Efficiency in piezoelectric isolators may be degraded by surface acoustic waves propagating in undesired directions through the piezoelectric medium. For example, a surface acoustic wave may propagate from a transmitter in a direction that is opposite the direction of the receiver. The energy associated with this wave is wasted. The inventors have developed techniques for promoting propagation of surface acoustic waves towards the receiver while limiting propagation in the opposite direction. These techniques involve acoustic reflectors. Additionally, the inventors have developed techniques for limiting propagation of surface acoustic waves beyond the receiver, as these waves may inadvertently travel to other regions of the chips, potentially leading to interference, crosstalk, and other negative effects. These techniques involve acoustic absorbers.

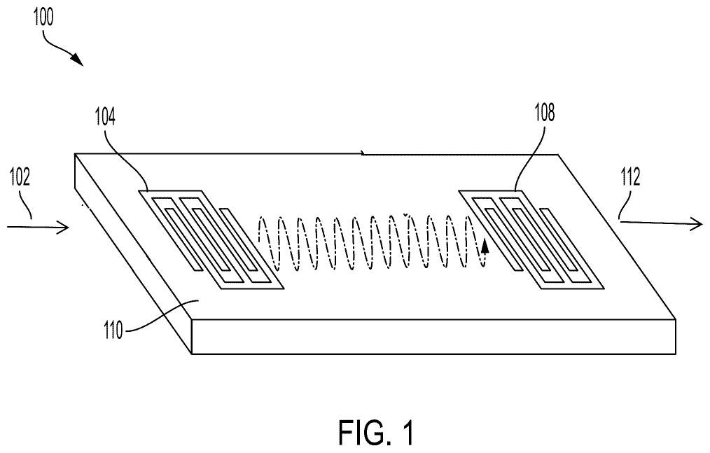

FIG. 1 illustrates a piezoelectric isolator 100. The isolator may be a microscale isolator in that any dimension of the isolator may be in the order of tens, hundreds or thousands of μm. In some embodiments, the isolator may be a nanoscale isolator in that any dimension of the isolator may be in the order of tens, hundreds or thousands of nm. Piezoelectric isolator 100 may be integrated on a chip with other circuits and/or other electronic devices (not shown in FIG. 1). For example, piezoelectric isolator 100 may be co-integrated with other piezoelectric isolators on the same chip. Additionally, or alternatively, piezoelectric isolator 100 may be co-integrated on the same chip with electronic circuits including transistors, such as signal generators, amplifiers, rectifiers, envelop detectors, signal converters and filters, among others. Correspondingly, the components and materials of piezoelectric isolator 100 may be compatible with those of a chip (e.g., silicon, sapphire and gallium nitride substrates), and circuits. In some embodiments, the isolator may be configured to galvanically isolate a first circuit or device from a second circuit or device. The first circuit or device may not share the same ground as the second circuit or device and/or may be operating at a different voltage domain (e.g., a higher voltage) than the second circuit or device. In some embodiments, the isolator may be configured to pass data through the isolation barrier such that a first circuit or device may communicate with a second circuit or device.

In some embodiments, local electric fields can occur following the first circuit or device supplying an input electric signal. The piezoelectric isolator can include components that are affected by high levels of local electric fields. As an example, the piezoelectric isolator can include a piezoelectric material such as a crystal, and a local electric field can be created in a region of that piezoelectric material during operation. In particular, the piezoelectric material may be able to withstand electric fields up to a threshold, which defines the electric breakdown of the material. Electric breakdown is a phenomenon by which the insulating properties of a dielectric or semiconductor material break down under high electric fields, leading to a sudden increase in electrical conductivity. When the electric field across the material exceeds the threshold, the material becomes conductive, thereby allowing current to flow through it. As a result, the ability of the material to provide isolation is diminished or compromised. As discussed herein, the inventors have appreciated that it can be beneficial to avoid regions in which electric field magnitude is larger than the breakdown electric field. The piezoelectric isolator may include means for reducing the magnitude of local electric fields that can be created during operation. The inventors have further appreciated that it can be beneficial to increase breakdown electric field. The piezoelectric isolator may include means for increasing the breakdown electric field. Reducing the magnitude of the electric field in regions where the electric field magnitude would otherwise be large, coupled with an increase in the breakdown electric field, enhances the ability of the isolator to provide galvanic isolation.

As shown in FIG. 1, piezoelectric isolator 100 includes a piezoelectric substrate 110. The piezoelectric substrate may be provided as a standalone substrate or may be provided as a layer on or part of (e.g., in) another substrate, such as a silicon substrate of a chip or circuit.

Piezoelectric substrate 110 may include a piezoelectric material. The piezoelectric material may be selected based at least in part on compatibility with components and materials of a chip, silicon substrate, and circuit and related manufacturing processes. Further, the piezoelectric material may be selected based at least in part on its ability to produce acoustic waves (e.g., surface acoustic waves (SAW)) in response to an applied voltage. In some embodiments, the piezoelectric material may be lithium niobate (LiNbO₃). Lithium niobate is compatible with certain semiconductor manufacturing processes, making it particularly suitable for integration with electronic integrated circuits. Further, lithium niobate presents a relatively large piezoelectric coupling coefficient. The piezoelectric coupling coefficient, often denoted by symbols such as kₚ, or dₚ, is a measure of the strength of the piezoelectric effect in a material. The piezoelectric coupling coefficient quantifies the magnitude of the effect in that it represents the ratio of the induced electric charge per unit mechanical stress or strain in the material. It should be noted that, in crystals, the piezoelectric effect is often highly anisotropic because the crystal structure dictates an orientation-dependent response to mechanical stress or electric field. The symmetry of the crystal lattice determines the number and orientation of axes along which the piezoelectric effect occurs. For example, in lithium niobate, the direction of maximum piezoelectricity typically corresponds to the crystallographic axis with the highest piezoelectric coefficient. Lithium niobate belongs to the trigonal crystal system, and it exhibits strong anisotropic properties, including its piezoelectric behavior. In lithium niobate, the direction of maximum piezoelectricity is often associated with the “z-axis” or the “c-axis” of the crystal lattice. This axis corresponds to the direction of the crystal's threefold symmetry axis. Along this axis, the piezoelectric coefficient is typically the highest. In some embodiments, the piezoelectric coupling coefficient along a particular direction (d₃₃) of Lithium niobate is about 8 pC/N.

Piezoelectric isolator 100 may include a piezoelectric transmitter disposed on the substrate. The piezoelectric transmitter may be configured to receive an electric signal and, in response to the electric signal and thanks to the piezoelectricity provided by the substrate, to produce an acoustic wave. As an example, piezoelectric transmitter 104 receives electric signal 102 and produces a surface acoustic wave. Electric signal 102 may be input from a circuit or device, which may be disposed on the same chip as the isolator or on another chip connected via wire bonding (or flip-chip bonding).

The piezoelectric transmitter 104 may include an electrode structure. In some embodiments, the electrode structure includes a pair of electrodes shaped to form a transducer. In some embodiments, the electrode structure includes electrodes configured so that when a voltage is applied, an acoustic wave is produced due to the piezoelectricity provided by the substrate. As shown in FIG. 1, the electrode structure of the piezoelectric transmitter may form an interdigitated transducer (IDT). Each electrode of the electrode structure may include fingers connected together and extending parallel to each other, for example. An electrode may include two fingers, four fingers, or another suitable amount of fingers, as the techniques are not so limited. The electrode structure may include two interdigitated sets of electrodes. The separation between the sets of fingers and the finger widths can dictate the resonant frequency of the transmitter, and as a result, the frequency of the emitted acoustic wave. In some embodiments, the resonant frequency may be in the MHz or GHz bands. In some embodiments, the spacing between the fingers of the piezoelectric transmitter may be engineered such that the transmitter has a resonant frequency to support surface acoustic waves forming with a frequency in a desired range.

The piezoelectric transmitter is acoustically coupled to a piezoelectric receiver through the piezoelectric material. In some embodiments, a surface acoustic wave (SAW) 106 may propagate through the piezoelectric material from the piezoelectric transmitter to the piezoelectric receiver. The SAW may propagate along a propagation axis A, such as shown in FIG. 1. Axis A identifies the primary axis of acoustic propagation from the transmitter to the receiver. As such, the majority of the acoustic energy produced by the transmitter travels in a direction that is parallel to axis A. The orientation of axis A may be defined by the geometry of the electrode structure of the transmitter. For example, in embodiments in which the electrode structure includes parallel fingers, axis A may be perpendicular to the direction along which the fingers extend.

It should be noted that the piezoelectric material need not extend continuously from the transmitter to the receiver. Rather, in some embodiments, a first pocket of piezoelectric material may be disposed in correspondence with the transmitter and a second, separate pocket of piezoelectric material may be disposed in correspondence with the receiver. In this respect, the piezoelectric material can be viewed as acoustically coupling the transmitter with the receiver partially. The first pocket of piezoelectric material forms acoustic waves when signals are applied to the transmitter. The second pocket of piezoelectric material assists the receiver in producing electric signals from acoustic waves.

As shown in FIG. 1, the example piezoelectric isolator 100 includes a piezoelectric receiver 108 disposed on the substrate. The piezoelectric receiver 108 may include an electrode structure. The electrode structure of the piezoelectric receiver may form an interdigitated transducer (IDT). The electrode structure may include two fingers, four fingers, or another suitable amount of fingers, as the techniques are not so limited. The electrode structure may include two interdigitated sets of electrodes. The piezoelectric receiver may have symmetry about one axis. The piezoelectric receiver may have the same shape as the transmitter in some embodiments. The piezoelectric receiver may be tuned similarly to the piezoelectric transmitter such that a surface acoustic wave received at the resonant frequency is collected by the receiver. Correspondingly, the spacing between the fingers of the piezoelectric receiver may be tuned to the same frequency as that of the piezoelectric transmitter. In some embodiments, the fingers of the receiver may be oriented perpendicular to axis A, thereby maximizing collection of acoustic energy by the receiver.

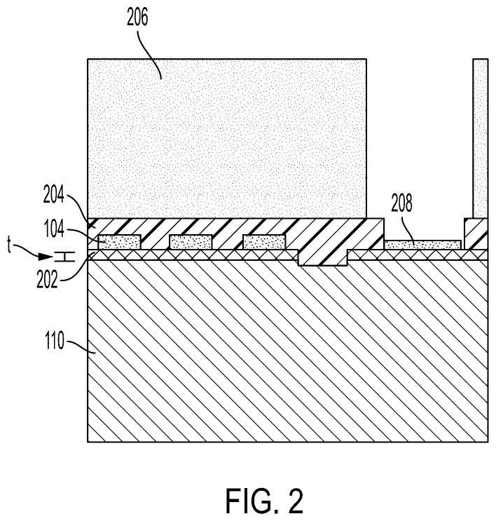

FIG. 2 shows a sectional view of a piezoelectric isolator. For example, FIG. 2 may represent a portion of the isolator of FIG. 1 (e.g., a portion of the transmitter or a portion of the receiver). The isolator may include the piezoelectric substrate 110 and piezoelectric transmitter 104 (e.g., as described in relation to FIG. 1). As noted above, piezoelectric substrate 110 may be defined as a layer of a substrate made of certain material (e.g., lithium niobate) or may be a standalone substrate. The electrode structure of the piezoelectric transmitter may be formed of a conductive material. As an example, the piezoelectric transmitter may be formed of a metal such as aluminum (Al), gold (Au) or copper (Cu). While FIG. 2 shows a cross-section including the transmitter, the cross-section of the receiver may appear the same, in some embodiments. Further, the receiver (while not shown in FIG. 2) may be formed of a conductive material, such as aluminum.

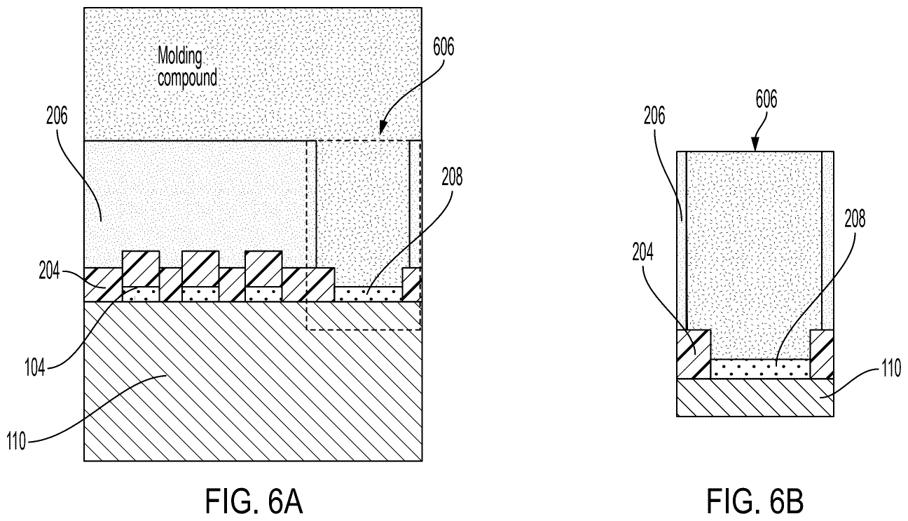

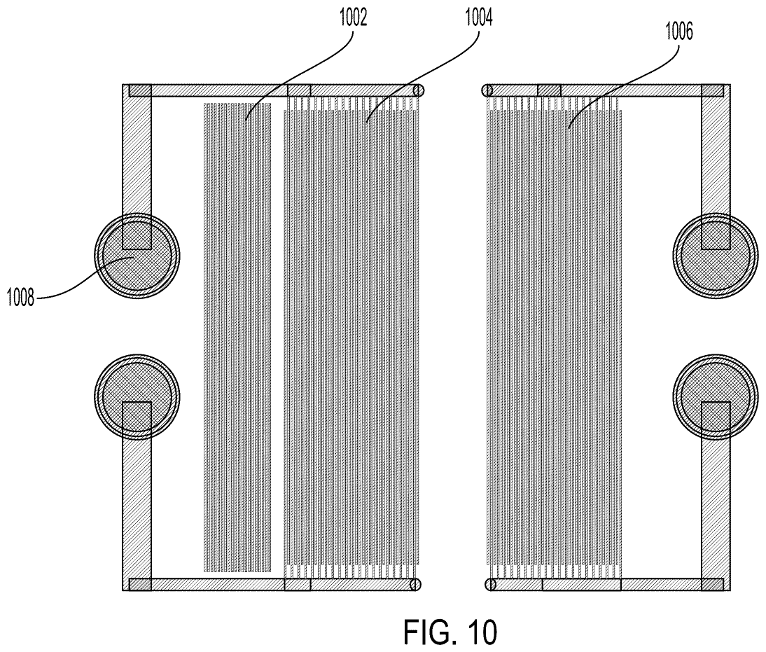

As shown in FIG. 2, a pad 208 may be included with the isolator. The pad may be made of a conductive material such as aluminum or gold. The pad may be configured to electrically couple to the piezoelectric transmitter (e.g., as described in relation to FIG. 10). In some embodiments, the pad may be configured to electrically couple to a circuit or device via wire bonding. Pad 208 may be electrically coupled to the fingers of the electrode structure, thereby providing electrical access to the transmitter. In this depiction, the pad is exposed in a recess, although the recess may ultimately be filled, for example with a molding compound (as shown in FIG. 6A).

As discussed herein, the piezoelectric isolator may include means for reducing local electric fields near the piezoelectric transmitter. Materials with a relatively high dielectric constant may increase the local electric field. As an example, Lithium Niobate may have a dielectric constant between 27 and 85, depending on the direction of the crystal (this is due to the anisotropic nature of Lithium Niobate). The relatively high dielectric constant of Lithium Niobate can result in regions of very high electric field, especially near the electrodes of the transmitter (or receiver). Unless proper measures are taken, as described herein, the electric field may exceed the breakdown electric field of the material in those regions, thereby leading to electric breakdown. The inventors have recognized that including means for reducing local electric fields can allow for more stable operation of an isolator which includes materials susceptible to breakdown.

FIG. 2 shows a piezoelectric isolator which includes an example of such means. In some embodiments, a dielectric layer 202 is included in the isolator to reduce local electric fields near the electrodes. Dielectric layer 202 may have a relatively low dielectric constant such as below 10. In some embodiments, dielectric layer 202 includes silicon nitride (SiN) or aluminum nitride or boron nitride or aluminum oxide or silicon dioxide, although other materials are also possible. Silicon nitride may be characterized by a dielectric constant of 7.5. Correspondingly, the dielectric material layer may have a dielectric constant less than the dielectric constant of the piezoelectric material.

A material for the dielectric layer, such as silicon nitride, may be chosen in part due to a compatibility with chips and the techniques used for processing chips. The thickness t of the added material, when formed, may be in the micron or nanometer range (including for example between 100 nm and 300 nm, although other ranges are possible).

In some embodiments, the dielectric layer 202 may be disposed between the piezoelectric transmitter and the piezoelectric material, such as the piezoelectric material of piezoelectric substrate 110. Similarly, a dielectric layer 202 may be disposed between the piezoelectric receiver and the piezoelectric material. The dielectric material layer disposed between the piezoelectric transmitter and the piezoelectric material, including a material such as silicon oxide or silicon nitride, may produce means for reducing a local electric field. In particular, at the edges of the electrode structures, local regions of high electric fields may be created. In some embodiments, the shape of the electrode may affect the local electric fields created. As an example, contacts with a rectangular shape (e.g., as shown in FIGS. 1 and 2) may have an increased occurrence of local electric fields. Including the dielectric material proximate the edges of the electrodes can, in some embodiments, reduce voltage spikes at those locations. Protecting against voltage spikes can aid in reducing breakdown. The isolator may therefore include means to reduce a local electric field near the electrodes.

Referring again to FIG. 2, the electrode structure may be covered by a dielectric material layer 204. The dielectric material layer may cover the electrode structure on one side, two sides, and/or all sides. The dielectric material layer 204 may include silicon oxide (SiO₂). The dielectric material layer 204 may be covered by another dielectric material layer 206 (e.g., as described further in relation to FIGS. 6A-6B). The dielectric material layer 206 may cover the dielectric material layer 204 on one side and/or all sides. The dielectric material layer 206 may be disposed on the other dielectric material 204, in some embodiments. Dielectric material layer 206 may include a polymer. As further discussed below, dielectric material layer 204 may have a first thickness and dielectric material layer 206 may have a second, greater thickness. As an example, dielectric material layer 204 may have a thickness less than 2 micrometers (microns) and dielectric material layer 206 may have a thickness greater than 2 micrometers (microns).

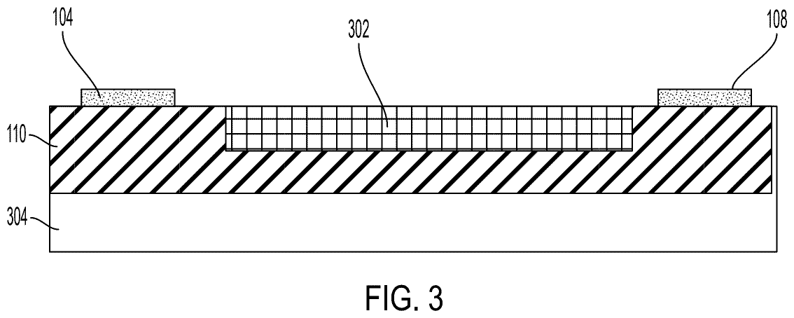

As discussed herein, it may be desirable to have an increased breakdown electric field so as to provide a greater margin against spikes of electric field. FIG. 3 shows a sectional view of a piezoelectric isolator including means for increasing a breakdown electric field between the piezoelectric transmitter and the piezoelectric receiver. The means may be included in a region of (or a region adjacent to) wave propagation.

In some embodiments, the means for increasing a breakdown electric field between the piezoelectric transmitter and receiver includes a dielectric material region disposed between the piezoelectric transmitter and receiver. The dielectric material region may include a well formed into a piezoelectric material. The dielectric material region may include a continuous region in some embodiments or may include multiple, discrete regions in other embodiments. In such other embodiments, the multiple discrete regions may include a same material or may include different dielectric materials. The dielectric material region may be adjacent the top surface of the substrate. The dielectric material region may not be entirely surrounded by piezoelectric material (e.g., not covered at a top surface of the dielectric material region). The dielectric material region may have a thickness that is between 10 nanometers and 20 microns (e.g., between 1 micron and 5 microns), or any value within that range. Other ranges are also possible.

As shown in FIG. 3, a dielectric material region 302 is disposed between piezoelectric transmitter 104 and piezoelectric receiver 108 disposed on a substrate. The example isolator of FIG. 3 is shown disposed on a substrate 304. In some embodiments, substrate 304 may be a silicon substrate. In some embodiments, substrate 304 may include the piezoelectric material of substrate 110.

In some embodiments, the piezoelectric material of substrate 110 may have a dielectric strength, and the dielectric material region 302 may have a dielectric strength that is greater than the dielectric strength of the piezoelectric material. The dielectric strength of a material is a measure of its ability to withstand an electric field without undergoing electrical breakdown. In simpler terms, it is the maximum electric field magnitude that a material can withstand without experiencing electric breakdown. By increasing the breakdown electric field in the region in which surface acoustic waves propagate from the transmitter to the receiver (e.g., near the top surface of the substrate), the likelihood of undergoing electric breakdown is reduced, thereby enhancing galvanic isolation.

In some embodiments, the piezoelectric material may include Lithium Niobate and the dielectric material region may include silicon dioxide. Silicon dioxide may have a dielectric strength of 10 MV/cm which may be greater than a dielectric strength of Lithium niobate. The means for reducing the local electric field may therefore include silicon dioxide.

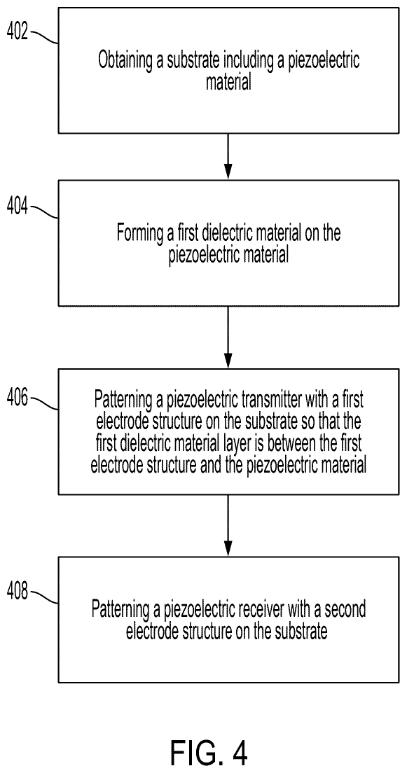

FIG. 4 shows a flowchart of a method for manufacturing a piezoelectric isolator. At step 402, a substrate including a piezoelectric material is obtained. In some embodiments, the obtained substrate may be piezoelectric substrate 110 or substrate 304 (e.g., as shown in FIG. 3). The piezoelectric material may be Lithium Niobate, zinc oxide, gallium nitride, aluminum nitride, lithium tantalate and quartz, although other materials are also possible.

At step 404, a dielectric material may be formed on the piezoelectric material. In some embodiments, the first dielectric material may include silicon nitride or other materials. As discussed herein, the piezoelectric material may have a first dielectric constant and the dielectric material layer may have a second dielectric constant less than the first dielectric constant.

At step 406, a piezoelectric transmitter with a first electrode structure may be patterned so that the dielectric material layer is between the first electrode structure and the piezoelectric material. The patterning may be performed using techniques commonly used for patterning conductive structures. Step 406 may include photolithographically fabricating the electrode structure. As described in relation to FIG. 2, including the dielectric material layer between the piezoelectric transmitter (e.g., including the first electrode structure) and the piezoelectric material may produce means for reducing a local electric field, and in particular, near the edges of the electrode structures.

At step 408, a piezoelectric receiver may be patterned with a second electrode structure on the substrate. The patterning may be performed using techniques commonly used for patterning conductive structures. Step 408 may include photolithographically fabricating the electrode structure. The piezoelectric receiver may be acoustically coupled to the piezoelectric transmitter (e.g., as described in relation to FIG. 1).

The method shown by the flowchart of FIG. 4 may include additional steps and may include fewer steps than shown. In some embodiments, the steps may be performed in an order not shown in FIG. 4, as the techniques are not so limited. As an example, the piezoelectric receiver may be patterned prior to or at the same time as patterning the piezoelectric transmitter.

Optionally, the method shown in FIG. 4 may include an additional step of forming a region of dielectric material in the substrate (e.g., as described in relation to FIG. 3). The additional step of forming the dielectric material region may be performed prior to the patterning steps or after the patterning steps. Forming the region of dielectric material may include etching through the piezoelectric material and, subsequently, filling the recessed region or well from the etch with a dielectric material (e.g., silicon dioxide).

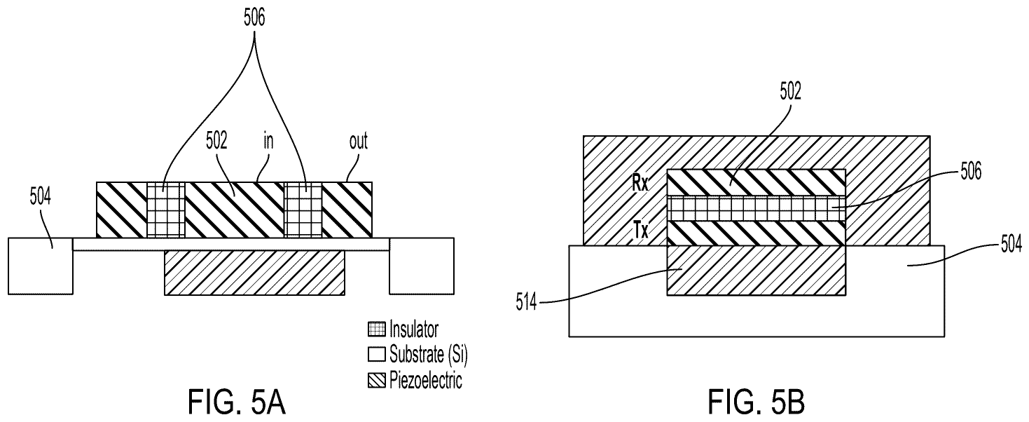

The isolators described above are planar in nature. As a result, acoustic coupling between the transmitter and the receiver is achieved through acoustic waves propagating inside the substrate. However, non-planar implementations are also possible. FIG. 5A shows a sectional view of a piezoelectric isolator including a non-planar arrangement of the piezoelectric isolator layers. The piezoelectric isolator shown in FIG. 5A includes piezoelectrical material 502, such as a piezoelectric substrate. The piezoelectric material may include Lithium Niobate, Aluminum nitride, gallium nitride in some embodiments, although other materials are also possible. The isolator shown in FIG. 5A also includes an insulator material 506. Examples of materials that may be used for insulator material 506 include PZT, AlN, GaN, AlScN, ScAlN, HfO, among others. The insulator and piezoelectric materials may be disposed on a substrate 504. Substrate 504 may be a chip substrate such as a silicon substrate. The piezoelectric isolator may include a transmitter and receiver (e.g., as described in relation to FIG. 1). Waves may propagate through the piezoelectric material 502 above the top plane of the substrate.

FIG. 5B shows a sectional view of a piezoelectric isolator including another example of a non-planar arrangement. As shown in FIG. 5B, the piezoelectric isolator may include piezoelectrical material 502, such as a piezoelectric substrate. The piezoelectric material may include any of the materials listed herein, or other materials. The isolator shown in FIG. 5B also includes insulator material 506. The insulator and piezoelectric materials may be disposed on substrate 504. Substrate 504 may be a chip substrate such as a silicon substrate. The piezoelectric isolator may include a transmitter and receiver (e.g., as described in relation to FIG. 1). Waves may propagate through the piezoelectric material 502 (e.g., in a vertical direction relative to a surface of the substrate 504 at which the piezoelectric material is proximate to). As shown in FIG. 5B, region 514 may include a vacuum, air, or a polymer, such as for wire-bonding applications (described in relation to FIG. 6A).

The inventors have recognized and appreciated that it may be desirable to have a relatively thick layer of material on top of the electrodes. This is because a thick layer of material can aid in confining high electric fields, providing a pathway for non-vacuum sealed packaging while enabling wirebonding between chiplets within the same package. In some circumstances, it may be desirable to package the isolator without having to resort to vacuum-supporting packages, which can increase complexity and cost and reduce reliability. Instead, non-vacuum packages may be used in some embodiments, including packages using molding compounds covering the isolator (e.g., SOIC and SSOP packages). However, packages that do not support vacuum are more susceptible to the formation of electric arcs, whereby the electrical breakdown of a gas produces a prolonged electrical discharge. The inventors have recognized that embedding the wire bond into a thick dielectric reduces the risk of producing electric arcs.

As shown in FIG. 6A, dielectric material layer 206 may be disposed on dielectric material layer 204. Dielectric material layer 204 may not have a planar surface in some embodiments. In some embodiments, dielectric material layer 204 may be formed as a conformal layer such as shown in FIG. 6A. However, planar profiles for dielectric material layer 204 are also possible. Dielectric layer 204 may be made of a material having a relatively low dielectric field and/or a relatively high dielectric strength (e.g., SiO₂), thereby limiting the likelihood of breakdown near the electrodes. Unfortunately, the typical growth rate of SiO₂ on semiconductor substrates makes it impractical to grow layers that are more than about 2 microns in thickness. Thus, an additional dielectric material (206) is provided on top of the lower dielectric material to provide the desired thickness. The additional dielectric material may include polymer, and may be more than 1 or 2 microns in thickness (e.g., between 1 micron and 20 microns or between 1 micron and 10 microns). Thus, dielectric material 204 and dielectric material 206 may have different thicknesses. In some embodiments, a further layer of dielectric material may be disposed between dielectric material 204 and dielectric material 206. The material may be chosen to release mechanical stress that may otherwise form due to the presence of dielectric material 204 on the substrate, thereby improving reliability. Additionally, or alternatively, the material may be chosen to improve the temperature coefficient of frequency (TCF) of the microscale isolator structure.

FIG. 6B shows an enlarged view of region 606 in FIG. 6A. As shown in FIG. 6B, the dielectric material layer 206 may not overlap with dielectric material layer 204 in recess 606 (the recess may ultimately be filled by a molding compound). In some embodiments, dielectric material layer 206 may be etched to expose at least a portion of dielectric material layer 204 in the recess. Dielectric material layer 204 may be etched to expose pad 208 while retaining the portion of material within the opening of the dielectric material 206 as shown in FIG. 6B. Openings of two different sizes may result from the use of different photomasks to define dielectric material layer 206 and dielectric material 204. In some embodiments, including openings of differing sizes can reduce the local electric field near the pad.

The inventors have further recognized and appreciated techniques for enhancing the efficiency of piezoelectric isolators while at the same time limiting spurious modes that may otherwise degrade the performance of the isolator. Efficiency in piezoelectric isolators may be degraded by acoustic waves propagating in undesired directions through the piezoelectric medium. For example, a surface acoustic wave may propagate from a transmitter in a direction that is opposite the direction of the receiver. The energy associated with this wave is wasted. The inventors have developed techniques for promoting propagation of acoustic waves toward the receiver while limiting propagation in the opposite direction.

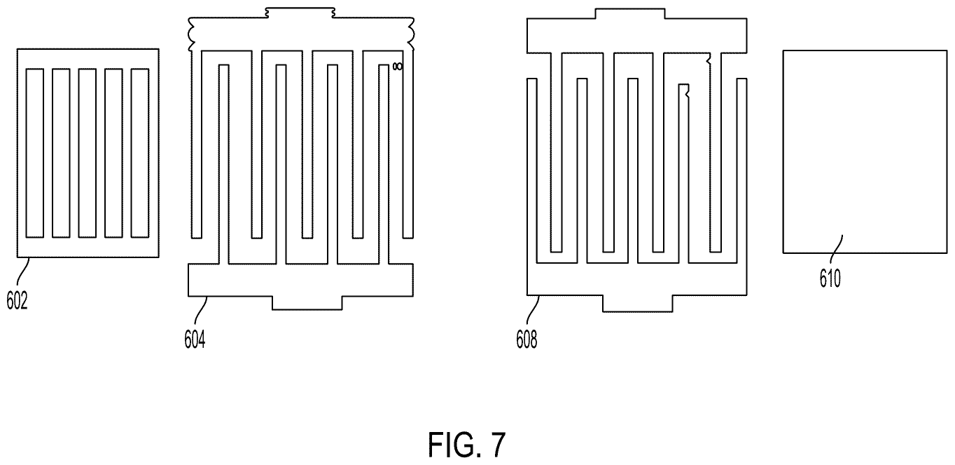

FIG. 7 illustrates a top view of components of a piezoelectric isolator (e.g., the piezoelectric isolator 100 shown in FIG. 1) including means for promoting propagation of surface acoustic waves in a first direction on the substrate and limiting propagation of surface acoustic waves on the substrate in a second direction opposite the first direction. The means may include an acoustic reflector 602 and an acoustic absorber 610.

As shown in FIG. 7, the isolator may include a transmitter 604 which may be configured in a suitable way such as piezoelectric transmitter 104 of FIG. 1. In some embodiments, each electrode set may include two fingers as shown in FIG. 1 or four fingers as shown in FIG. 7, as the techniques are not so limited. The example isolator of FIG. 7 may include a receiver 608 which may be configured in a suitable way such as piezoelectric receiver 108 of FIG. 1. In some embodiments, each electrode set may include two fingers as shown in FIG. 1 or four fingers as shown in FIG. 7, as the techniques are not so limited. The transmitter 604 and receiver 608 may be disposed on a substrate including a piezoelectric material (e.g., as shown in FIG. 1). The transmitter may be disposed between the acoustic reflector and the receiver, and the receiver may be disposed between the acoustic absorber and the transmitter.

The isolator may be configured to receive an input electric signal (e.g., as shown in FIG. 1). As described in relation to FIG. 1, an acoustic wave may resultingly propagate in the piezoelectric material. The acoustic wave may propagate in a first direction towards the receiver and in a second, opposite direction. In some embodiments, the acoustic reflector 602 is configured to reflect waves produced by the transmitter directed away from the receiver. Once reflected, the wave travels in the desired direction-toward the receiver. In some embodiments, the acoustic reflector 602 is configured as an electrode structure. In some embodiments, the electrode structure may be of the same or different thickness as an electrode structure of the transmitter. The electrode structure may include a set of fingers, which may be arranged periodically. The set of fingers may have a spacing that determines a prohibited wavelength band-wave having wavelengths in this band produce destructive interference when traveling away from the receiver, and as a result are reflected. Correspondingly, the acoustic reflector may include a periodic structure such that certain waves do not propagate through the periodic structure and as a result, reflect back (e.g., towards the receiver). The reflector may be positioned at a distance from the transmitter so that the waves reflected from the reflector add to the waves produced by the transmitter in phase. In this way, constructive interference is produced in the direction of travel towards the receiver. In some embodiments, reflectors may be included at other locations of the substrate to promote and/or enhance efficiency of wave propagation from the transmitter to the receiver.

In some embodiments, waves may propagate beyond the receiver 608. In other words, the receiver may collect less that the totality of the acoustic energy directed towards the receiver. The existence of acoustic energy passing beyond the receiver without being absorbed poses a challenge. This energy may inadvertently travel towards other isolators disposed on the same chip. If absorbed by other isolator receivers, this energy may lead to cross talk. To prevent this negative effect, an acoustic absorber 610 may be added to attenuate acoustic waves and to limit propagation of the waves escaping from the receiver. The acoustic absorber may include a layer of absorbing material configured to attenuate acoustic waves. The layer of absorbing material may include a polymer material, such as polyimide, SU8, photoresists and molding compound or other dielectric materials with high absorption coefficient that may include adhesives and oils.

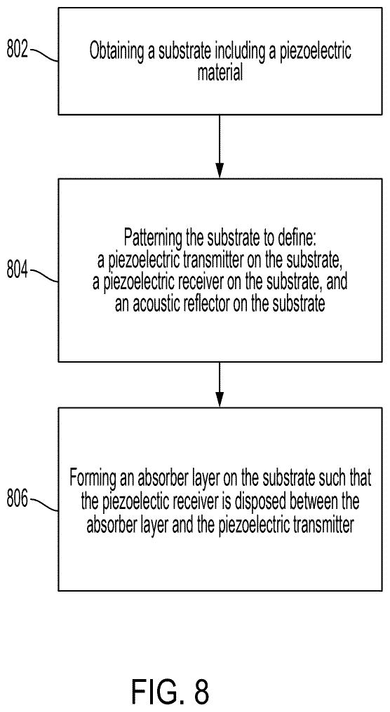

FIG. 8 shows a flowchart of a method for manufacturing a piezoelectric isolator, such as described in relation to FIG. 7. The method may include step 802 in which a substrate including a piezoelectric material is obtained. In some embodiments, the obtained substrate may be a piezoelectric substrate 110 (e.g., as shown in FIG. 1) or a substrate 304 (e.g., as shown in FIG. 3). The piezoelectric material may be Lithium Niobate.

At step 804, the substrate may be patterned to define a piezoelectric transmitter, piezoelectric receiver, and an acoustic reflector. The piezoelectric transmitter, piezoelectric receiver, and acoustic reflector may include electrode structures on the substrate. In some embodiments, the acoustic reflector may have a periodic structure. Patterning the acoustic reflector may result in the piezoelectric transmitter being disposed between the acoustic reflector and the piezoelectric receiver. The patterning may be performed using techniques commonly used for patterning conductive structures. In some embodiments, step 804 includes photolithographically fabricating a plurality of structures such as the transmitter, receiver, and/or reflector.

At step 806, an absorber layer may be formed on the substrate such that the piezoelectric receiver is disposed between the absorber layer and the piezoelectric transmitter. The absorber layer may be configured to attenuate acoustic waves.

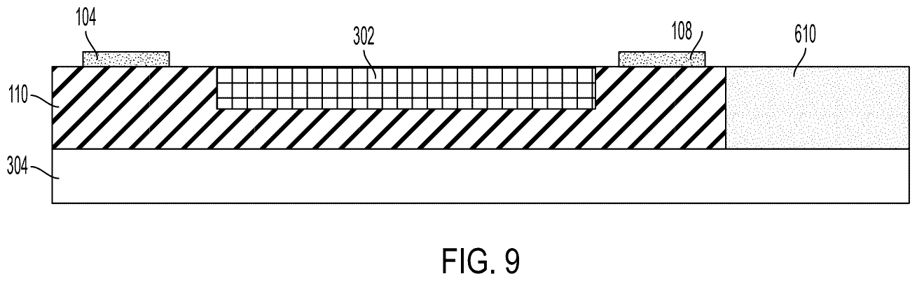

The method shown by the flowchart of FIG. 8 may include additional steps and may include fewer steps than shown. In some embodiments, the steps may be performed in an order not shown in FIG. 8, as the techniques are not so limited. As an example, the method shown in FIG. 8 may include an additional step of forming a region of dielectric material in the substrate (e.g., as described in relation to FIG. 3). The additional step of forming the dielectric material region may be performed prior to the patterning step(s) or after the patterning step(s). Performing at least some of the steps of FIG. 8 (e.g., at least steps 802 and 806) may result in the piezoelectric isolator shown in FIG. 9.

FIG. 9 shows a sectional view of the piezoelectric isolator shown in FIG. 3 including acoustic absorber 610 formed as a region that absorbs acoustic energy. Acoustic absorber 610 may be disposed on substrate 304 as shown in FIG. 9. Alternatively, or additionally, acoustic absorber 610 may be disposed on piezoelectric substrate 110.

FIG. 10 shows a top view of a photomask for a piezoelectric isolator (e.g., piezoelectric isolator 100 shown in FIG. 1). The photomask is an example of a photomask that may be used to photolithographically fabricate a piezoelectric transmitter, piezoelectric receiver, and acoustic reflector of an isolator (e.g., as described at step 804 of FIG. 8). As shown in FIG. 10, the fabrication may result in a piezoelectric transmitter 1004 being disposed between an acoustic reflector 1002 and a piezoelectric receiver 1006. The piezoelectric transmitter, piezoelectric receiver, and acoustic reflector may be fabricated according to the techniques as described herein (e.g., in relation to FIG. 8). FIG. 10 also shows pads 1008. The pads may include at least a first and second contact electrically coupled to the piezoelectric transmitter and piezoelectric receiver, respectively.

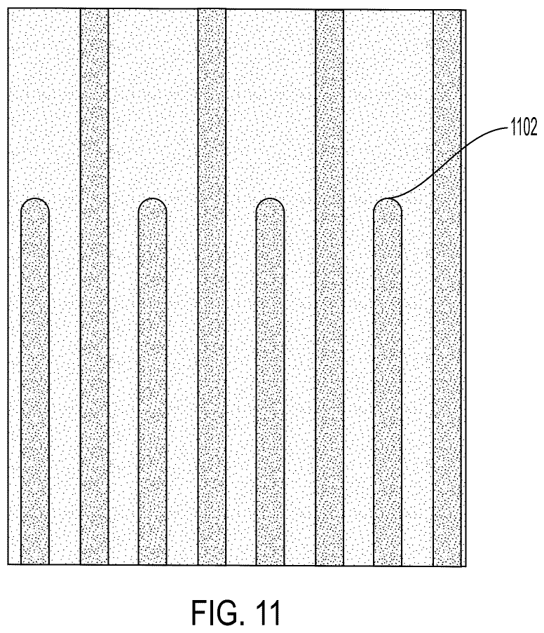

FIG. 11 shows a top view of an example electrode structure including electrode edges 1102. As shown in FIG. 11, the electrode corners may be rounded (as opposed to being rectangular). Including rounded edges can reduce local electric fields around the electrode edges, thus further reducing the likelihood of electric breakdown near the electrodes and improving the high voltage endurance of the isolators. In some embodiments, the electrode structures described herein may include rounded edges. As an example, the piezoelectric transmitter 104 of FIG. 1 may be made with an electrode structure with rounded corners, in some embodiments. As an additional example, the transmitter 604 shown in FIG. 7 may include an electrode structure with rounded edges.

The inventors have further recognized and appreciated that, in some applications, it may desirable that a group of receivers share the same transmitter, or that a group of transmitters share the same receiver. The former scenario would enable architectures in which the same signal is to be delivered to multiple destination, while at the same time providing galvanic isolation. The latter scenario would enable architectures in which a receiver is to receive signals from multiple sources, while at the same time providing galvanic isolation.

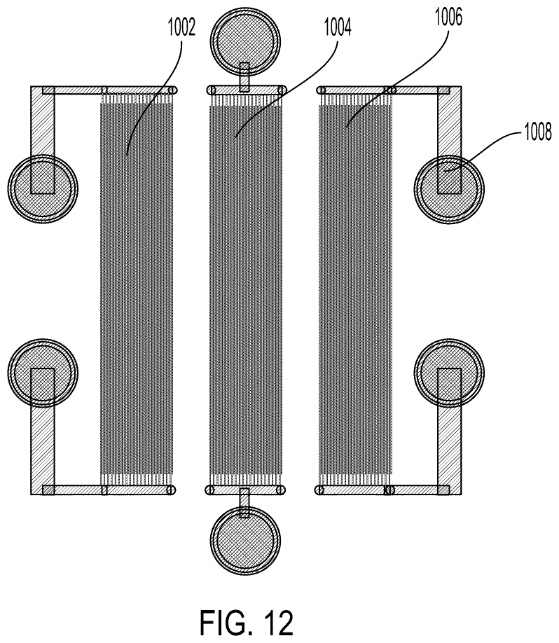

Thus, in some embodiments, more than one transmitter or receiver may be included in a piezoelectric isolator. FIG. 12 shows a top view of a photomask for a piezoelectric isolator including one or more transmitters or receivers. The photomask is an example of a photomask that may be used to photolithographically fabricate a piezoelectric transmitter and piezoelectric receiver of an isolator (e.g., as described in part in relation to steps 406 and 408 of FIG. 4).

As shown in FIG. 12, a first electrode structure 1004 may be patterned between a second and third electrode structure 1002 and 1006, respectively. The electrode structures may be formed as first, second, and third interdigitated transducers (IDT). In some embodiments, the electrode structures include rounded corners (e.g., as shown in FIG. 11). FIG. 12 also shows pads 1008. The pads may include at least a first and second contact electrically coupled to each electrode structure, respectively.

In some embodiments, first electrode structure 1004 is configured as a piezoelectric transceiver and the second and third electrode structures 1002 and 1006 are configured as piezoelectric receivers. As such, a transmitter is disposed between two receivers. This architecture takes advantage of the fact that the transmitter naturally transmits waves in both directions. In such an embodiment, a reflector may be omitted since a receiver is disposed on either side of the transmitter so as to receive waves that may propagate in either direction from the transmitter.

Correspondingly, a piezoelectric isolator, such as including photolithographically fabricated components, may include a substrate with a piezoelectric material such as lithium niobate, a piezoelectric transmitter, a first piezoelectric receiver disposed on the substrate, and a second piezoelectric receiver, disposed on the substrate, in which the piezoelectric transmitter is acoustically coupled to the first piezoelectric receiver and the second piezoelectric receiver through the piezoelectric material. In some embodiments, the isolator can be further processed to include a dielectric material layer such as a first dielectric material layer disposed between an electrode structure of the piezoelectric transmitter and the piezoelectric material, in which the first dielectric material layer is made of silicon nitride. Optionally, a first dielectric material region may be formed between the piezoelectric transmitter and at least one piezoelectric receiver and/or a second dielectric material region disposed between the piezoelectric transmitter and another piezoelectric receiver. In such an embodiment, the piezoelectric material may have a first dielectric strength, and the first and second dielectric material regions may have a second dielectric strength greater than the first dielectric strength.

The piezoelectric isolator of FIG. 12 may also include an acoustic absorber (e.g., acoustic absorber 610 shown in FIG. 7) such that the first piezoelectric receiver or the second piezoelectric receiver is disposed between the piezoelectric transmitter and the acoustic absorber. The piezoelectric isolator may include an additional acoustic absorber proximate the piezoelectric receiver that is not disposed between the other acoustic absorber and the piezoelectric transmitter.

Optionally, first electrode structure 1004 of FIG. 12 may be configured as a piezoelectric receiver and the second and third electrode structures 1002 and 1006 are configured as piezoelectric transmitters. As such, a receiver is disposed between two transmitters. In such an embodiment, an acoustic absorber may be omitted since a transmitter is disposed on either side of the receiver. In such an embodiment, multiple transmitters may contribute to one load. Optionally, each of the transmitters may have an array of reflectors, as described in connection with FIG. 10.

Correspondingly, a piezoelectric isolator, such as including photolithographically fabricated components, may include a substrate with a piezoelectric material such as lithium niobate, a piezoelectric receiver, a first piezoelectric transmitter disposed on the substrate, and a second piezoelectric transmitter disposed on the substrate, in which the piezoelectric receiver is acoustically coupled to the first piezoelectric transmitter and the second piezoelectric transmitter through the piezoelectric material. In some embodiments, the isolator can be further processed to include dielectric material layer such as a first dielectric material layer disposed between an electrode structure of the piezoelectric transmitter and the piezoelectric material, in which the first dielectric material layer is made of silicon nitride or aluminum nitride or aluminum oxide. Optionally, a first dielectric material region may be formed between the piezoelectric receiver and at least one piezoelectric transmitter and/or a second dielectric material region disposed between the piezoelectric receiver and another piezoelectric transmitter. In such an embodiment, the piezoelectric material may have a first dielectric strength, and the first and second dielectric material regions may have a second dielectric strength greater than the first dielectric strength.

The piezoelectric isolator of FIG. 12 may also include a first acoustic reflector such that the first piezoelectric transmitter is disposed between the first acoustic reflector and the piezoelectric receiver. Optionally, the piezoelectric isolator of FIG. 12 may also include a second acoustic reflector, such that a second piezoelectric transmitter is disposed between the second acoustic reflector and the piezoelectric receiver. The reflectors may be configured as the acoustic reflector 602 described in relation to FIG. 7. As an example, the acoustic reflector(s) may have a periodic structure.

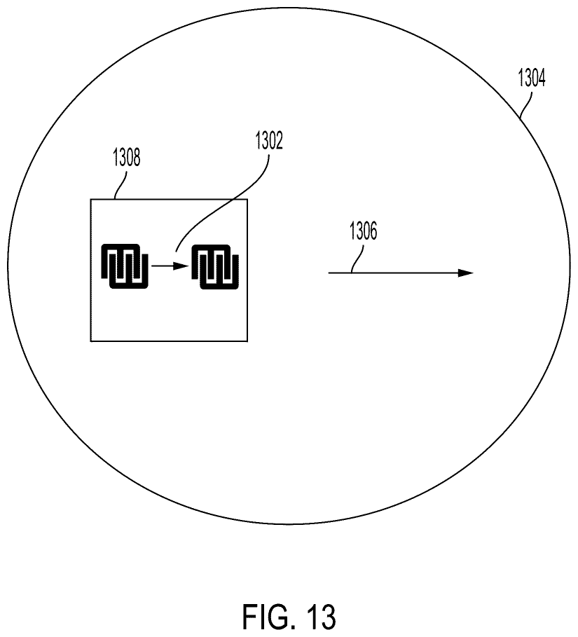

FIG. 13 shows a top view of a wafer 1304 (e.g., including at least one portion of the wafer before dicing) that may be used in manufacturing a piezoelectric isolator 1302 according to the techniques described herein. In some embodiments, piezoelectric isolator 1302 includes a piezoelectric transmitter and a piezoelectric receiver. Boundary 1308 represents the perimeter of the isolator die upon being diced off the wafer. As shown in FIG. 13, the wafer may be characterized by a direction 1306. Direction 1306 represents the direction of maximum piezoelectric coupling of the piezoelectric material embedded in the substrate. This means that the ability of the piezoelectric material (which is anisotropic in nature) to produce acoustic waves from an electric signal, and vice versa, is maximized along direction 1306.

In some embodiments, an isolator may be patterned on the wafer such that the primary axis (1302) of propagation of acoustic waves is parallel or perpendicular to direction 1306. This enhances the efficiency of the isolator. The primary axis of propagation of acoustic waves may be set by the shape of the transmitter or by the electrical input. For example, arranging the transmitter to have finger electrodes that are parallel to one another produces a primary axis of propagation that is perpendicular to the orientation of the fingers. To further maximize collection of energy at the receiver, the receiver may include finger electrodes oriented in the same direction as the transmitter's fingers.

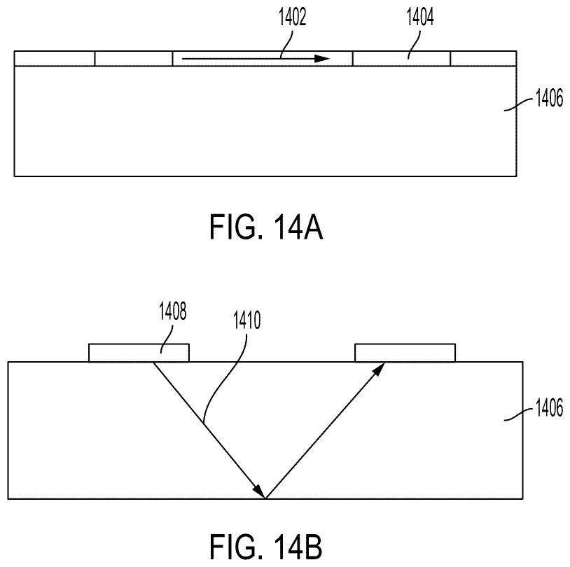

Thus, the piezoelectric transmitter(s) and the piezoelectric receiver(s) of the piezoelectric isolator may be in line with the direction of maximum piezoelectric coupling of the substrate. FIG. 14A shows a sectional view of a piezoelectric isolator including an indication 1402 of the direction of propagation. The piezoelectric isolator may include a patterned layer 1404 and a substrate 1406. As shown, the patterned layer (e.g., a transmitter and receiver) of the piezoelectric isolator is in line with the direction of maximum piezoelectric coupling of the substrate (e.g., when patterning, the wafer was oriented in the direction of coupling).

In other embodiments, it may be useful to form a substrate in such a way that the direction of maximum piezoelectric coupling is transverse relative to the surface of the substrate. In this implementation, acoustic waves are preferentially generated to propagate deep into the substrate, as opposed to parallel to the surface. One example of such an implementation is shown in FIG. 14B. Here, direction 1410 represents the direction of maximum piezoelectric coupling. Notably, direction 1410 is transverse relative to the top surface of the substrate. In some embodiments, the location of the transmitter relative to the receiver may be chosen so that acoustic waves reach the receiver upon reflection from a surface located deep into the substrate, as shown in FIG. 14B.

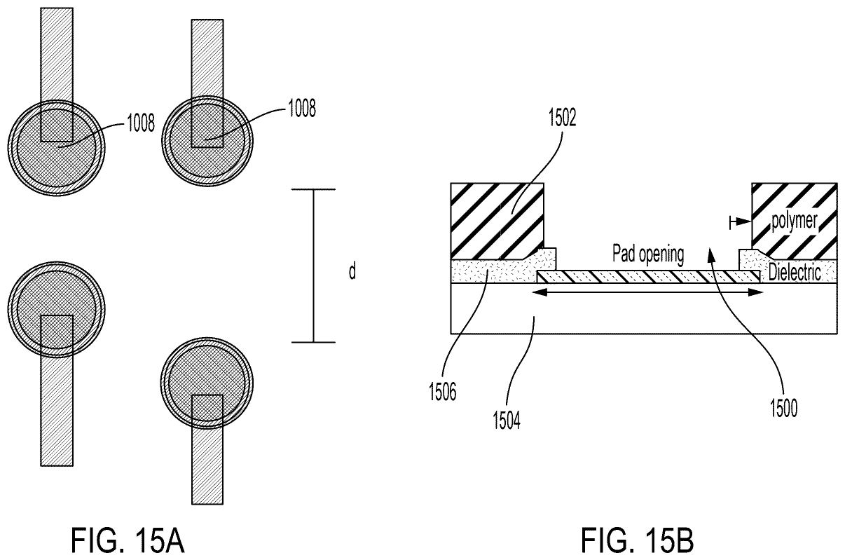

FIG. 15A shows a top view of pads 1008 of a piezoelectric isolator (e.g., the piezoelectric isolator of FIG. 10) in two different configurations having different electrode spacing. As shown in FIG. 15A, the pads, such as a first and second contact, may be separated by a distance d. The distance d may be selected such that spurious waves that may otherwise arise from the presence of standing waves are reduced. To prevent standing waves. In some embodiments, the distance is not a multiple of a resonant wavelength of the piezoelectric transmitter. As a result, the contacts suppress spurious waves and reduce unwanted resonance modes. The shape of the pads may be circular or polygonal (e.g., rectangular) with no sharp points.

FIG. 15B shows a sectional view of a pad opening 1500 of a piezoelectric isolator such as for a pad (e.g., pad 1008 of photomask shown in FIG. 15A) once patterned and included in a piezoelectric isolator structure. As shown in FIG. 15B, the piezoelectric isolator may include polymer 1502, a substrate 1504, and dielectric (e.g., silicon dioxide) 1506. The pad may have a width of approximately 150 micrometers. A first pad opening may have a width of approximately 122 micrometers. A second pad opening may extend by approximately 10 micrometers on each side of the first opening (e.g., extend by 20 micrometers in total). It should be noted that the dimensions shown in FIG. 15B are not limiting and are provided solely for purposes of illustration.

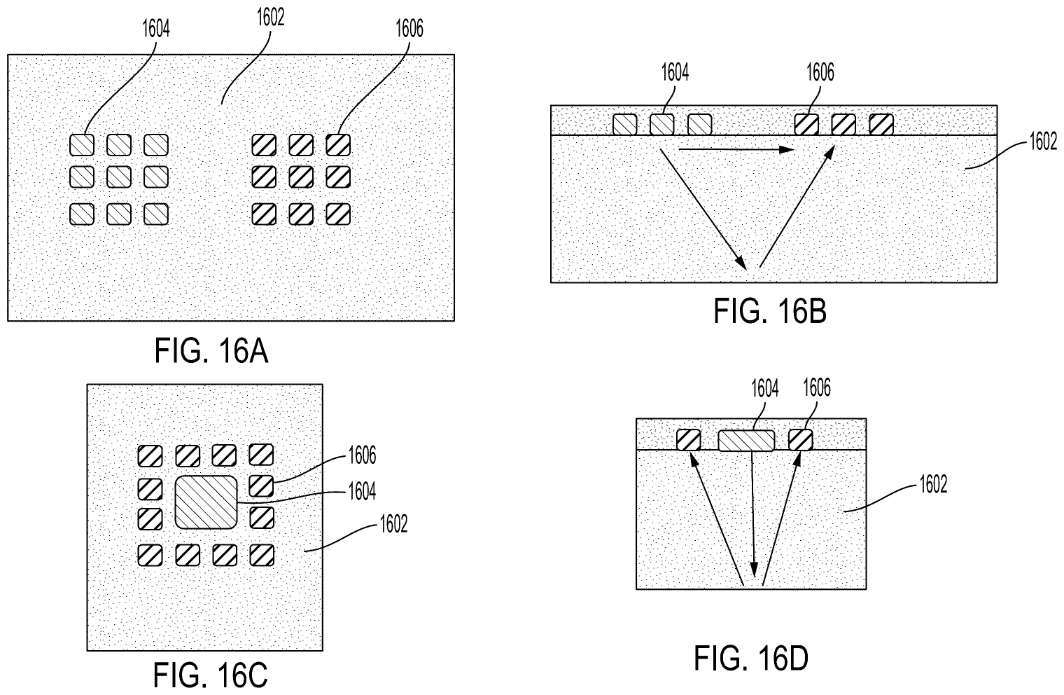

The implementations described above include IDTs as examples of piezoelectric transducers (Tx and RX). However, the piezoelectric transducers may be implemented in other ways, as discussed in connection with FIGS. 16A-16D. It should be noted that the aspects of the present technology described above in connection with FIGS. 1-15 may be applied to the piezoelectric transducers shown in FIGS. 16A-16D.

FIG. 16A shows a top view of an alternative transducer arrangement. In this example, piezoelectric transmitter 1604 is formed as an array of electrodes disposed on piezoelectric material 1604. The electrodes may have any shape, and may have rounded corners in some embodiments. Piezoelectric receiver 1606 may have a similar arrangement.

FIG. 16B shows a sectional view of the piezoelectric isolator of FIG. 16A. The piezoelectric transmitter 1604 may produce surface acoustic waves and bulk waves. In some embodiments, beamforming techniques may be used to direct the majority of the energy along a particular angle—the angle at which, upon reflection as shown in FIG. 16B, the acoustic energy propagates towards the piezoelectric receiver. Beamforming may be accomplished by applying phase-shifted versions of the same signal to the various electrodes of the array. For example, the electrodes of the array may share the same ground, but may be connected to a corresponding phase shifter.

As shown in FIG. 16B, the bulk waves may propagate outside the plane in which the surface acoustic waves propagate. In some embodiments, the waves (e.g., surface acoustic waves and bulk waves) propagate in at least one direction of maximum piezoelectric coupling.

FIG. 16C shows a top view of another transducer arrangement. As shown in FIG. 16C, piezoelectric transmitter 1604 may be arranged to be surrounded by the piezoelectric receiver. In the depicted implementation, the piezoelectric transmitter includes a single electrode, although other implementations include an array of electrodes. The piezoelectric receiver includes a set of electrodes disposed around the perimeter of the piezoelectric transmitter. FIG. 16D shows a sectional view of the piezoelectric isolator of FIG. 16C. As shown in FIG. 16D, as bulk acoustic waves propagated into the substrate and back (upon reflection), the width of the wave spatially broadens due to diffraction. The spatial broadening allows different sections of the wave to reach different electrodes of the piezoelectric receiver.

What is claimed is:

1. A piezoelectric isolator, comprising:
a substrate comprising a piezoelectric material;
a first piezoelectric receiver, disposed on the substrate, having a first electrode structure;
a piezoelectric transmitter, disposed on the substrate, having a second electrode structure; and
a second piezoelectric receiver, disposed on the substrate, having a third electrode structure, wherein the piezoelectric transmitter is acoustically coupled to the first piezoelectric receiver and the second piezoelectric receiver at least partially through the piezoelectric material.

2. The piezoelectric isolator of claim 1, further comprising an acoustic absorber, wherein the first piezoelectric receiver is disposed between the piezoelectric transmitter and the acoustic absorber.

3. The piezoelectric isolator of claim 2, wherein the acoustic absorber comprises a layer of absorbing material configured to attenuate acoustic waves.

4. The piezoelectric isolator of claim 1, wherein the first and the second electrode structure comprises rounded corners.

5. The piezoelectric isolator of claim 1, wherein the piezoelectric transmitter defines a primary axis of acoustic propagation that is parallel to a direction of maximum piezoelectric coupling of the substrate.

6. The piezoelectric isolator of claim 1, further comprising first and second contacts electrically coupled to the piezoelectric transmitter that are separated by a distance, and wherein the distance does not support spurious waves generation.

7. The piezoelectric isolator of claim 6, wherein the distance is not a multiple of a resonant wavelength of the piezoelectric transmitter.

8. The piezoelectric isolator of claim 1, wherein the piezoelectric material is made of lithium niobate.

9. The piezoelectric isolator of claim 1, further comprising a first dielectric material layer disposed between the second electrode structure and the piezoelectric material.

10. The piezoelectric isolator of claim 1, wherein the first electrode structure forms a first interdigitated transducer (IDT), the second electrode structure forms a second IDT, and the third electrode structure forms a third IDT.

11. The piezoelectric isolator of claim 1, further comprising a first dielectric material region disposed between the piezoelectric transmitter and the first piezoelectric receiver and a second dielectric material region disposed between the piezoelectric transmitter and the second piezoelectric receiver.

12. The piezoelectric isolator of claim 11, wherein:
the piezoelectric material has a first dielectric strength, and
the first and second dielectric material regions have a second dielectric strength greater than the first dielectric strength.

13. The piezoelectric isolator of claim 1, further comprising electronic circuitry co-integrated with the substrate.

14. The piezoelectric isolator of claim 1, wherein the piezoelectric transmitter comprises a plurality of electrodes and a plurality of phase shifters, coupled to the electrodes, configured to perform beamforming.

15. A piezoelectric isolator, comprising:
a substrate comprising a piezoelectric material;
a first piezoelectric transmitter, disposed on the substrate, having a first electrode structure;
a piezoelectric receiver, disposed on the substrate, having a second electrode structure; and
a second piezoelectric transmitter, disposed on the substrate, having a third electrode structure, wherein the piezoelectric receiver is acoustically coupled to the first piezoelectric transmitter and the second piezoelectric transmitter at least partially through the piezoelectric material.

16. The piezoelectric isolator of claim 15, further comprising:
a first acoustic reflector, wherein the first piezoelectric transmitter is disposed between the first acoustic reflector and the piezoelectric receiver; and
a second acoustic reflector, wherein the second piezoelectric transmitter is disposed between the second acoustic reflector and the piezoelectric receiver.

17. The piezoelectric isolator of claim 16, wherein the first acoustic reflector comprises a periodic structure.

18. The piezoelectric isolator of claim 15, further comprising a first dielectric material region disposed between the first piezoelectric transmitter and the piezoelectric receiver and a second dielectric material region disposed between the second piezoelectric transmitter and the piezoelectric receiver.

19. The piezoelectric isolator of claim 15, wherein the first piezoelectric transmitter defines a primary axis of acoustic propagation that is parallel to a direction of maximum piezoelectric coupling of the substrate.
